(19) United States
(12) Patent Application Publication
(10) Pub. No.: US 2010/0097761 A1
(43) Pub. Date: Apr. 22, 2010

(54) MOTHERBOARD

(75) Inventor: CHIH-SHENG HSIEH, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/264,921

(22) Filed: Nov. 5, 2008

(30) Foreign Application Priority Data
Oct. 16, 2008 (CN) 200810304953.1

(51) Int. Cl. H05K 7/20; H05K 7/00

(52) U.S. Cl. 361/695; 361/760; 361/690; 361/694

(57) ABSTRACT

A motherboard includes a mounting area, a number of first mounting holes, and a plurality of second mounting holes. The mounting area is configured to support an electronic component. The first mounting holes are configured to mate with a first fan. The second mounting holes are configured to mate with a second fan having a greater size than the first fan. The first and second mounting holes are located surrounding an exterior of the mounting area, a first distance between each of the first mounting holes and a center point of the mounting area is longer than a second distance between one of the second mounting holes and the center point of the mounting area. The first and second fans are configured to cool the electronic component.

### BACKGROUND

1. Technical Field

The present disclosure relates to motherboards and, particularly, to a motherboard with holes for mounting fans.

2. Description of the Related Art

A computer system includes various components such as a motherboard, a central processing unit (CPU), a storage device such as a hard disc drive, and input/output devices mounted on the motherboard. Many of these devices, including the CPU, generate heat when the computer system is operating. The computer system may include a CPU fan mounted directly on the CPU, to cool the CPU.

Conventionally, CPU fans may only be mounted to a dedicated motherboard. CPU fans designed for one kind of motherboard cannot be attached to another kind of motherboard.

What is needed, therefore, is to provide a motherboard to overcome the above-mentioned shortcoming.

### BRIEF DESCRIPTION OF THE DRAWINGS

FIG. 1 is a schematic view of an embodiment of a motherboard.

FIG. 2 is a schematic view of the motherboard of FIG. 1 together with a first fan.

FIG. 3 is a schematic view of the motherboard of FIG. 1 together with a second fan.

### DETAILED DESCRIPTION

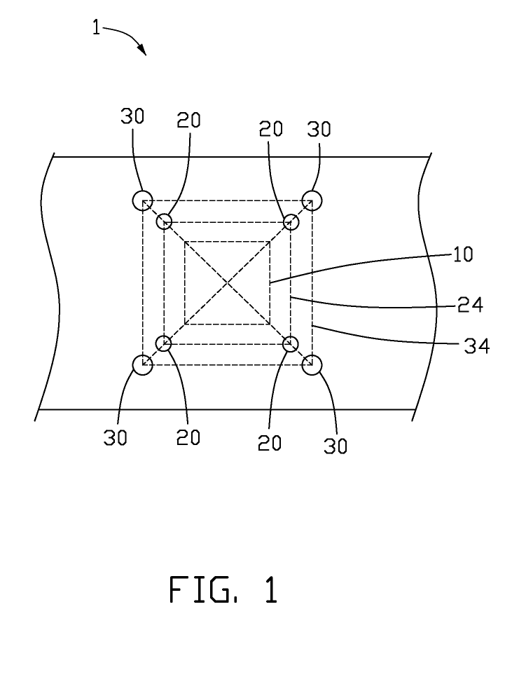

Referring to FIG. 1, a motherboard 1 includes a mounting area 10, four first mounting holes 20, and four second mounting holes 30. The mounting area 10 is a rectangular area configured to support a CPU. The four first mounting holes 20 and the four second mounting holes 30 are located surrounding an exterior of the mounting area 10. In the illustrated embodiment of the drawing, the first mounting holes 20 are located along extension lines of the diagonals of the mounting area 10, and the second mounting holes 30 are located further along on the same extension lines of the diagonals. Each of the second mounting holes 30 is located at a corner of a rectangular area 34, which is defined outside the mounting area 10, and shares the same center point of the mounting area 10. Each of the first mounting holes 20 is located at a corner of a rectangular area 24, which is defined inside the rectangular area 34, and shares the same center point of the rectangular area 34. Each of the first mounting holes 20 is the same distance from the center point of the mounting area 10, and each of the second mounting holes 30 are the same distance from the center point of the mounting area 10.

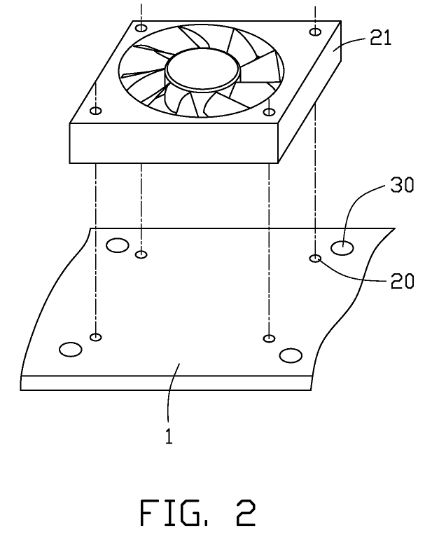

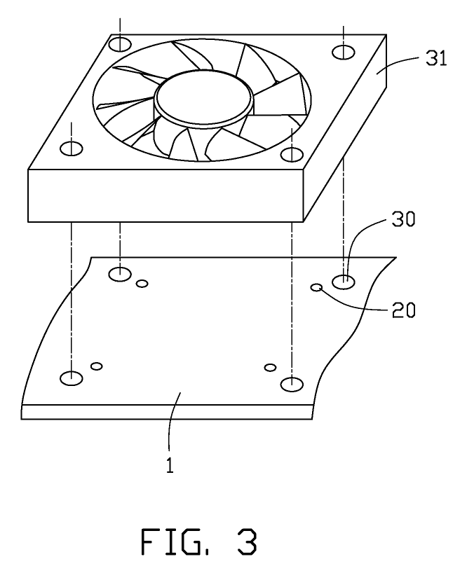

Referring to FIGS. 2 and 3, The four first mounting holes 20 are configured to secure a first fan 21 as shown in FIG. 2, such as an Intel socket 775 CPU fan. The four second mounting holes 30 are configured to secure a second fan 31 having a greater size than the first fan, as shown in FIG. 3, such as an Intel socket 1366 CPU fan. Therefore, both of the first fan and the second fan can fit on the motherboard 1. Therefore, users can select any one of the first fan and the second fan for mounting on the mounting area 10 as desired.

In the current embodiment, the mounting area 10 is configured to mount a CPU beneath the selected fan as an example. In other embodiments, electronic components other than a CPU may be used.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skills in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A motherboard comprising:
a mounting area configured to support an electronic component;
a plurality of first mounting holes configured to secure a first fan; and
a plurality of second mounting holes configured to secure a second fan having a greater size than the first fan;
wherein the first and the second mounting holes are located surrounding an exterior of the mounting area in pairs, a first distance between each of the first mounting holes and a center point of the mounting area is longer than a second distance between one of the second mounting holes which forms a pair with the first mounting hole and the center point of the mounting area; wherein the first and second fans are configured to cool the electronic component.

2. The motherboard of claim 1, wherein the mounting area is a rectangle.

3. The motherboard of claim 2, wherein the plurality of first mounting holes comprises four first holes, each of the four first holes is arranged along an extension line of a diagonal of the mounting area; wherein the plurality of second mounting holes comprises four second holes, each of the second holes is arranged along the extension line of the diagonal of the mounting area.

4. A motherboard comprising:
a first rectangular area;
a second rectangular area defined inside the first rectangular area, and sharing a same center with the first rectangular area;
a plurality of first holes configured to secure a first fan; and
a plurality of second holes configured to secure a second fan;
wherein each of the first holes is located at a corner of the first rectangular area, each of the second holes is located at a corner of the second rectangular area.

5. The motherboard of claim 4, further comprising a mounting area configured to hold an electronic component, the mounting area is defined inside the second rectangular area, and sharing a same center with the second rectangular area.

6. The motherboard of claim 5, wherein the mounting area has a rectangular shape.

7. The motherboard of claim 5, wherein two of the first holes and two of the second holes are defined along a first straight line superposed with a diagonal line of the mounting area, the other two of the first holes and the other two of the second holes are defined along a second straight line superposed with the other diagonal line of the mounting area.

8. A computer assembly comprising:
a motherboard;
a mounting area defined on the motherboard for mounting an electronic component, and having a center point;
a plurality of first holes defined in the motherboard configured to secure a first fan, each of the first holes being spaced a first distance apart from the center point of the mounting area; and
a plurality of second holes defined in the motherboard configured to secure a second fan, each of the second holes being spaced a second distance apart from the center point of the mounting area;
wherein the first and the second holes are located surrounding an exterior of the mounting area, the value of the first distance is greater than the value of the second distance.

9. The computer assembly of claim 8, wherein the plurality of first holes comprises four first holes, the second holes comprises four second holes, two of the four first holes and two of the four second holes are defined along a first straight line which goes through the center point of the mounting area, the other two of the four first holes and the other two of the four second holes are defined along a second straight line which goes through the center point of the mounting area.

10. The computer assembly of claim 9, wherein the mounting area is a rectangle, the first straight line is superposed with a diagonal line of the mounting area, the second straight line is superposed with the other diagonal line of the mounting area.

11. The computer assembly of claim 8, wherein the electronic component is a central processing unit.
